(19) United States
(12) Patent Application Publication
(10) Pub. No.: US 2026/0182350 A1
(43) Pub. Date: Jun. 25, 2026

(54) BONDING STRUCTURE FOR PARALLEL COMPLEMENTARY FIELD EFFECT TRANSISTOR (CFET)

(71) Applicant: Taiwan Semiconductor Manufacturing Company, Ltd., Hsin-Chu (TW)

(72) Inventors: Yung-Ta Chen, Taichung City (TW); Kuan-Kan Hu, Hsinchu (TW); Wei-Xiang You, Kaohsiung City (TW); Ku-Feng Yang, Hsinchu County (TW)

(21) Appl. No.: 19/195,994

(22) Filed: May 1, 2025

Related U.S. Application Data
(60) Provisional application No. 63/738,212, filed on Dec. 23, 2024.

(51) Int. Cl. H01L 23/528; H01L 21/768; H01L 23/522; H10D 30/00; H10D 30/01; H10D 30/43; H10D 62/10; H10D 84/85

(52) U.S. Cl. CPC H10W 20/435; H10D 30/014; H10D 30/0191; H10D 30/43; H10D 30/503; H10D 62/121; H10D 84/851; H10W 20/057; H10W 20/42

(57) ABSTRACT

A top tier device of a complementary field effect transistor (CFET) device a plurality of first transistors. A first bonding layer disposed over the top tier device. The first bonding layer includes a first dielectric layer and a plurality of first conductive components embedded in the first dielectric layer. A bottom tier device of the CFET includes a plurality of second transistors. A second bonding layer is disposed over the second device. The second bonding layer includes a second dielectric layer and a plurality of second conductive components embedded in the second dielectric layer. Each of the first conductive components is aligned with, and coupled to, a respective one of the second conductive components.

### PRIORITY DATA

The present application is a utility U.S. application of provisional U.S. application No. 63/738,212, filed on Dec. 23, 2024, entitled “Direct Hybrid Bonding to Achieve Parallel CFET Devices”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, as device sizes shrink, bonding alignment between different devices becomes more difficult. If devices are bonded but not aligned well, the device performance may not be optimal.

Therefore, although conventional methods of bonding IC structures have generally been adequate, they have not been entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device in the form of a FinFET according to various aspects of the present disclosure.

FIG. 1B is a planar top view of an IC device in the form of a FinFET according to various aspects of the present disclosure.

FIG. 1C is a cross-sectional side view of an IC device in the form of a GAA device according to various aspects of the present disclosure.

FIG. 1D is a cross-sectional side view of a portion of a complementary field effect transistor (CFET) according to various aspects of the present disclosure.

FIGS. 2-8 illustrate cross-sectional side views of IC structures undergoing a bonding process according to various aspects of the present disclosure.

FIG. 9 is a planar top view of an IC device according to various aspects of the present disclosure.

FIGS. 10-16 illustrate cross-sectional side views of IC structures undergoing a bonding process according to various aspects of the present disclosure.

FIG. 17 is a planar top view of an IC device according to various aspects of the present disclosure.

FIG. 18 is a block diagram of an IC fabrication facility according to various aspects of the present disclosure.

FIG. 19 is a flowchart illustrating a method of bonding IC devices according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor fabrication, and more particularly, to the bonding alignment of IC structures that include field-effect transistors (FETs), such as three-dimensional fin-shaped FETs (FinFETs) or gate-all-around (GAA) devices. In that regard, a FinFET device is a fin-like field-effect transistor device, and a GAA device is a multi-channel field-effect transistor device. FinFET devices and GAA devices have both been gaining popularity recently in the semiconductor industry, since they offer several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices or GAA devices for a portion of, or the entire IC chip.

However, in spite of the advantages offered by the FinFET devices and/or GAA devices, certain challenges may still remain in IC applications in which FinFET or GAA devices are implemented. For instance, modern manufacturing of ICs may entail bonding different IC structures together. However, as device sizes get scaled down, alignment between different IC structures may become more difficult. If devices are bonded but not aligned well, then device performance may be sub-optimal.

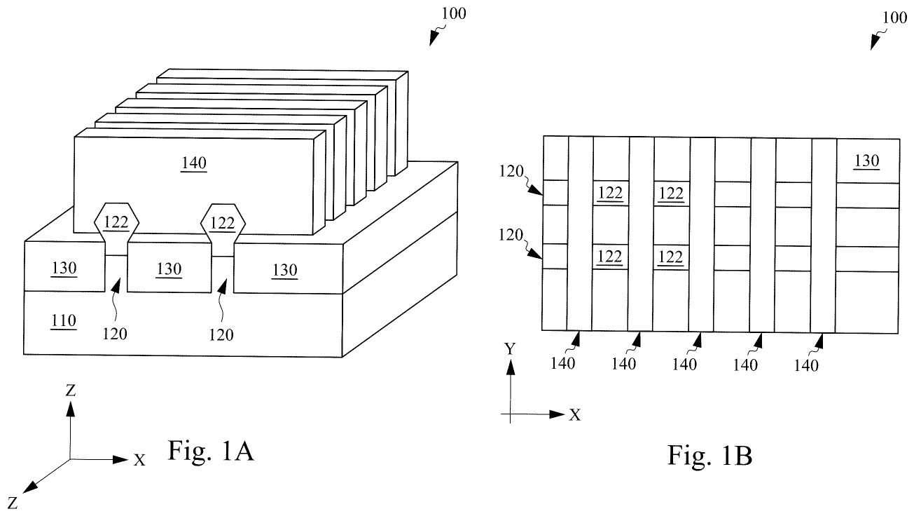

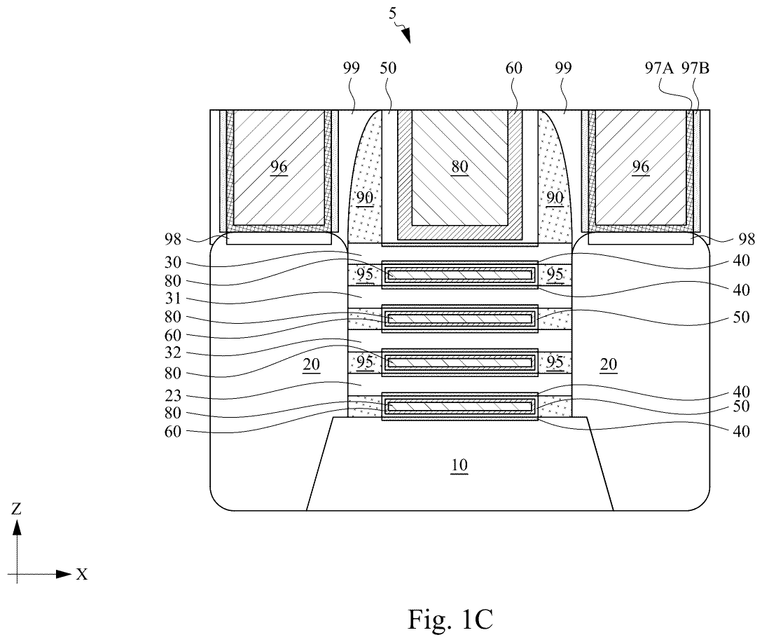

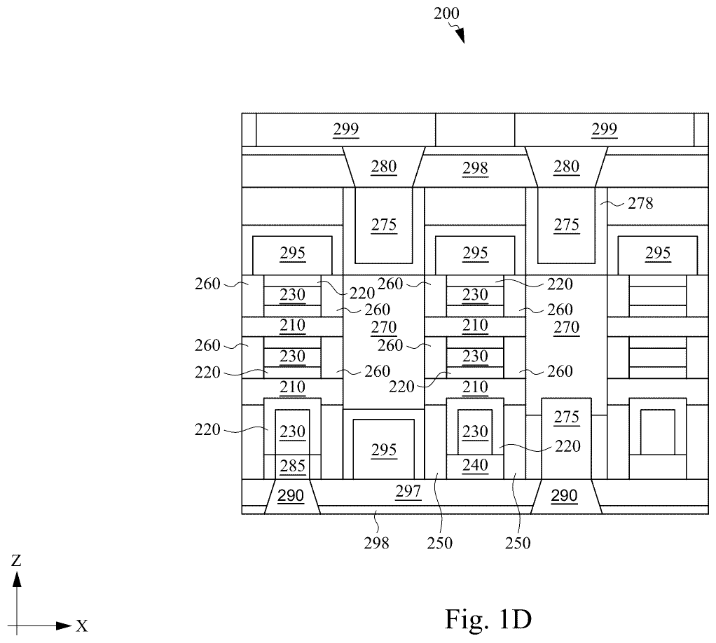

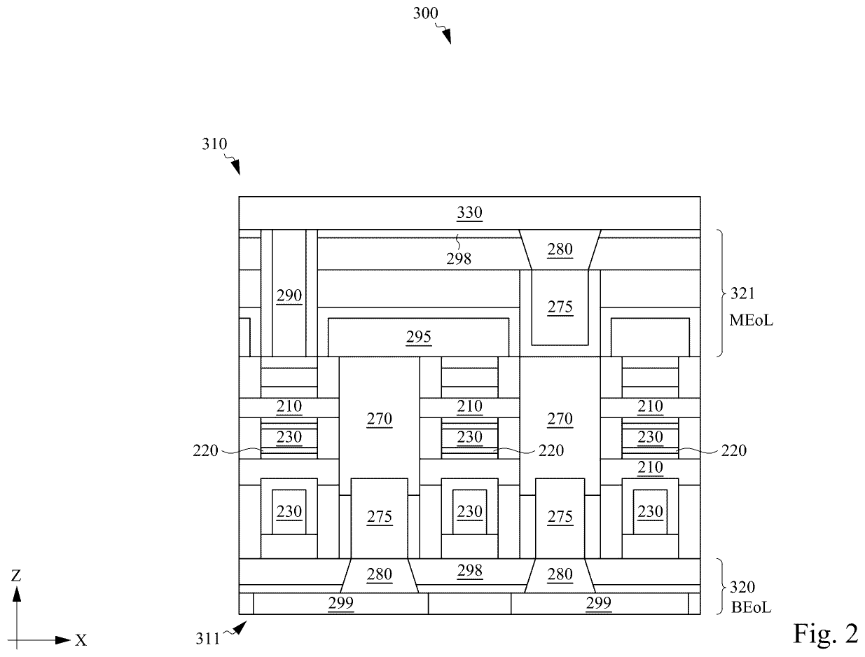

To address the issues discussed above, the present disclosure implements an electric assisted alignment scheme to improve the bonding alignment between different IC structures. In that regard, FIGS. 1A-1D illustrate example types of transistors that may be the subject of IC device bonding, and FIGS. 2-17 illustrate the various aspects of the bonding alignment scheme, as discussed below in more detail.

Referring now to FIGS. 1A-1D, these figures describe the basic structures of example FinFET and GAA devices. For example, FIGS. 1A and 1B illustrate a three-dimensional perspective view and a top view of a portion of an Integrated Circuit (IC) device 100, respectively. The IC device 100 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. Note that the present disclosure is not limited to any particular number of devices or device regions, or to any particular device configurations, unless otherwise claimed. For example, although the IC device 100 as illustrated is a three-dimensional FinFET device, the concepts of the present disclosure may also apply to planar FET devices or GAA devices.

Referring now to FIGS. 1A and 1B, a three-dimensional perspective view and a top view of a portion of an Integrated Circuit (IC) device 100 are illustrated, respectively. The IC device 100 may be an intermediate device fabricated during processing of an IC, or a portion thereof, that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells.

In the example shown in FIGS. 1A and 1B, the IC device 100 is a three-dimensional fin-shaped FET (FinFET) device. In that regard, a FinFET device is a fin-like field-effect transistor device, which has been gaining popularity recently in the semiconductor industry, since it offers several advantages over traditional Metal-Oxide Semiconductor Field Effect Transistor (MOSFET) devices (e.g., “planar” transistor devices). These advantages may include better chip area efficiency, improved carrier mobility, and fabrication processing that is compatible with the fabrication processing of planar devices. Thus, it may be desirable to design an integrated circuit (IC) chip using FinFET devices for a portion of, or the entire IC chip.

Referring to FIG. 1A, the IC device 100 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions, including nano-structures, are formed on the substrate 110. The active regions are elongated fin-like structures that protrude upwardly out of the substrate 110. The protrusion structure 120 may be interchangeably referred to as fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 100 also includes source/drain features 122 formed over the fin structures 120. The source/drain features 122 may include epi-layers that are epitaxially grown on the fin structures 120. The IC device 100 further includes isolation structures 130 formed over the substrate 110. The isolation structures 130 electrically separate various components of the IC device 100. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical polishing (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 100 also includes gate structures 140 formed over and engaging the fin structures 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIG. 1B, multiple fin structures 120 are oriented lengthwise along the X-direction, and multiple gate structures 140 are oriented lengthwise along the Y-direction, i.e., generally perpendicular to the fin structures 120. In many embodiments, the IC device 100 includes additional features such as gate spacers disposed along sidewalls of the gate structures 140, hard mask layer(s) disposed over the gate structures 140, and numerous other features.

FIG. 1C illustrates a diagrammatic cross-sectional side view of a portion of an IC device 5 fabricated according to embodiments of the present disclosure, where the IC device 5 is a gate-all-around (GAA) device and may be referred to as a GAA device 5 hereinafter. It is understood that the GAA device 5 may be an NFET in some embodiments, or it may be a PFET in other embodiments.

Referring to FIG. 1C, the cross-sectional view of the GAA device 5 is taken along an X-Z plane, where the X-direction (same X-direction as in FIG. 1A) is the horizontal direction, and the Z-direction (same Z-direction as in FIG. 1A) is the vertical direction. The GAA device 5 includes a fin structure 10, which may be similar to the fin structure 120 discussed above. In some embodiments, the fin structure 10 includes silicon. The GAA device 5 includes source/drain features 20, which may be similar to the source/drain features 122 discussed above. In embodiments where the GAA device 5 is an NFET, the source/drain features 20 include silicon phosphorous (SiP). In embodiments where the GAA device 5 is a PFET, the source/drain features 20 include silicon germanium (SiGe).

The GAA device 5 includes a plurality of channels, for example channels 30-33 as shown in FIG. 1C. The channels 30-33 each include a semiconductive material, for example silicon or a silicon compound. The channels 30-33 are nanostructures (e.g., having sizes that are in a range of a few nanometers) and may also each have an elongated shape and extend in the X-direction. In some embodiments, the channels 30-33 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 30-33 may be different from each other. For example, a length of the channel 30 may be less than a length of the channel 31, which may be less than a length of the channel 32, which may be less than a length of the channel 33. In some embodiments, each of the channels 30-33 may not have uniform thicknesses.

In some embodiments, a spacing (e.g., measured in the Z-direction) between the channels 30-33 (each channel from adjacent channels) is in a range between about nanometers (nm) and about 12 nm. In some embodiments, a thickness (e.g., measured in the Z-direction) of each of the channels 30-33 is in a range between about 5 nm and about nm. In some embodiments, a width (e.g., measured in the Y-direction of FIG. 1A) of each of the channels 30-33 is in a range between about 15 nm and about 150 nm. A plurality of interfacial layers (ILs) 40 may also be formed on the upper and lower surfaces of the channels 30-33.

The GAA device 5 also includes gate structures that are disposed over and in between the channels 30-33. The gate structures may include gate dielectric layers 50. In some embodiments, the gate dielectric layers 50 include a high-k gate dielectric. The gate structures further include one or more work function metal layers 60. In embodiments where the GAA device 5 is an NFET, the one or more work function metal layers 60 include N-type work function metal layers, such as TiAlC. In embodiments where the GAA device 5 is a PFET, the one or more work function metal layers 60 include P-type work function metal layers, such as TiN.

The gate structures also include fill metals 80. In the portion of the gate structure formed over the channels 30-33, the fill metal 80 are formed over the one or more work function metal layers 60. The one or more work function metal layers 60 have a U-shape and wrap around the fill metal 80, and the gate dielectric layer 50 also has a U-shape and wrap around the one or more work function metal layers 60. In portions of the gate structures formed between the channels 30-33, the fill metal 80 is circumferentially surrounded (in the cross-sectional view) by the one or more work function metal layers 60, which is then circumferentially surrounded by the gate dielectric layer 50. It is understood that the gate structures may also include a glue layer that is formed between the one or more work function metal layers 60 and the fill metal 80 to increase adhesion. However, for reasons of simplicity, such a glue layer is not specifically illustrated herein.

The GAA device 5 also includes gate spacers 90 and inner spacers 95 that are disposed on sidewalls of the gate dielectric layer 50. The inner spacers 95 are also disposed between the channels 30-33. The gate spacers and the inner spacers 95 may include a dielectric material, for example a low-k material such as SiOCN, SiON, SiN, or SiOC.

The GAA device 5 further includes source/drain contacts 96 that are formed over the source/drain features 20. The source/drain contacts 96 may include a conductive material such as cobalt, copper, aluminum, tungsten, or combinations thereof. The source/drain contacts 96 are surrounded by barrier layers, for example barrier layers 97A and 97B, which help prevent or reduce diffusion of materials from and into the source/drain contacts 96. In some embodiments, the barrier layer 97A includes TiN, and the barrier layer 97B includes SiN. A silicide layer 98 may also be formed between the source/drain features 20 and the source/drain contacts 96, so as to reduce the source/drain contact resistance. The silicide layer 98 may contain a metal silicide material, such as cobalt silicide in some embodiments.

The GAA device 5 further includes an interlayer dielectric (ILD) 99. The ILD 99 provides electrical isolation between the various components of the GAA device 5, for example between the gate structures and the source/drain contacts 96.

GAA devices may also offer advantages such as better chip area efficiency, improved carrier mobility, etc. As such, advanced IC chips may be implemented using the GAA devices as well. However, it is understood that the present disclosure is not limited to any particular number of devices or device regions, or to any particular device configurations, unless otherwise claimed. For example, although FinFET devices or GAA devices have been described as potential transistors that could be used to implement the IC chip or a portion thereof, the concepts of the present disclosure discussed in more detail below may also apply to IC chips implemented using planar FET devices as well.

FIG. 1D is a cross-sectional side view of a portion of a complementary field effect transistor (CFET) 200 illustrated along an X-Z plane. In some embodiments, the illustrated portion of the CFET 200 is a top tier device, which may include one or more GAA transistors (similar to the GAA device 150 discussed above with reference to FIG. 1C). The top tier device may be bonded to a bottom tier deice of the CFET in a bonding process of the present disclosure discussed below. It is understood, however, that the top tier device and the bottom tier device may have substantially similar or even identical structures (other than the types of conductivity) in some embodiments. In other embodiments, the top tier device may include n-type transistors, while the bottom tier device may include p-type transistors, or vice versa, but the rest of their respective device configurations may be substantially similar or identical. In any case, it is understood that the descriptions of the top tier device of the CFET 200 may apply to the bottom tier device as well, unless otherwise noted.

Referring to FIG. 1D, the portion of the CFET 200 includes a plurality of semiconductor layers, such as the semiconductor layers 210. The semiconductor layers 210 may be disposed vertically over one another in a stack, and collectively they may serve as the channel components of a GAA transistor of the portion of the CFET 200. In some embodiments, the semiconductor layers 210 each include silicon. In other embodiments, the semiconductor layers 210 may include another suitable type of semiconductor material.

The portion of the CFET 200 further includes a plurality of gate dielectric layers, such as gate dielectric layers 220. In some embodiments, the gate dielectric layers 220 each include a high-k dielectric layer, which may be a dielectric material having a dielectric constant that is greater than a dielectric constant of silicon dioxide (k≈3.9). For example, the high-k dielectric layer may be implemented using as HfO₂, HfSiO, HfSiO₄, HfSiON, HfLaO, HfTaO, HfTiO, HfZrO, HfAlOₓ, ZrO, ZrO₂, ZrSiO2, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, or a combination thereof. In the illustrated embodiment, the gate dielectric layers 220 may include a hafnium-based oxide (e.g., HfO₂) layer and/or a zirconium-based oxide (e.g., ZrO₂) layer. It is understood that the gate dielectric layers 220 may further include an interfacial layer that includes a dielectric material, such as SiO₂, SiGeOₓ, HfSiO, SiON, other dielectric material, or a combination thereof.

The portion of the CFET 200 further includes a plurality of gate electrode layers, such as gate electrode layers 230. The gate electrode layers 230 are formed on the gate dielectric layers 220 and include an electrically conductive material, such as Al, Cu, Ti, Ta, W, Mo, Co, TaN, NiSi, CoSi, TiN, WN, TiAl, TiAlN, TaCN, TaC, TaSiN, or a combination thereof. In some embodiments, the gate electrode layers 230 each include a work function layer and a fill-metal layer. The work function layer is an electrically conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or a combination thereof. Meanwhile, the fill metal layer is an electrically conductive bulk layer formed over the work function layer, and it may include materials such as Al, W, Cu, Ti, Ta, TiN, TaN, polysilicon, alloys thereof, or a combination thereof. In some embodiments, the gate electrode layers 230 may further include a barrier (blocking) layer. The barrier layer includes a material that prevents or eliminates diffusion and/or reaction of constituents between adjacent layers and/or promotes adhesion between adjacent layers, such as between the work function layer and the fill-metal layer. In some embodiments, the barrier layer includes metal and nitrogen, such as titanium nitride, tantalum nitride, tungsten nitride (e.g., W₂N), titanium silicon nitride (TiSiN), tantalum silicon nitride (TaSiN), or a combination thereof.

The gate dielectric layers 220 and the gate electrode layers 230 may be formed by a gate replacement process, in which dummy gate structures are replaced by functional gate structures that comprise the gate dielectric layers 220 and the gate electrode layers 230. The location and/or the dimensions of the dummy gate structures (and therefore the functional gate structures) may be defined at least in part by hard mask layers 240, which may include a dielectric material such as silicon nitride, silicon oxynitride, silicon carbide, silicon oxycarbide, silicon carbonitride, silicon oxycarbonitride, or a combination thereof. In some other embodiments, the hard mask layer 240 may include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), or a combination thereof. It is understood that a gate stack (or a gate structure) may be formed by the gate dielectric layers 220 and the gate electrode layers 230.

Gate spacers 250 are disposed along sidewalls of the portions of the gate stack disposed immediately adjacent to the hard mask layer 240, and inner spacers 260 are disposed along sidewalls of the other portions of the gate stack. The gate spacers 250 and the inner spacers 260 may include dielectric materials such as silicon oxide, silicon nitride, silicon oxynitride, silicon carbide, silicon carbonitride, silicon oxycarbide, silicon oxycarbonitride, or a combination thereof, though it is understood that the gate spacers 250 and the inner spacers 260 may include different types of materials and/or different configurations (e.g., different numbers of layers). For example, in some embodiments, the gate spacers 250 may include more than one set of spacers, such as seal spacers, offset spacers, sacrificial spacers, dummy spacers, main spacers, or a combination thereof. The various sets of spacers may have different compositions.

The portion of the CFET 200 further includes a plurality of source/drain regions 270 disposed on opposite sides of the gate stack. The source/drain regions 270 may be epitaxially grown, and they may be doped with n-type dopants and/or p-type dopants. For example, the source/drain regions 270 may include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). As another example, the source/drain regions 270 may include silicon germanium or germanium that is doped with boron, other p-type dopant, or a combination thereof (e.g., Si:Ge:B epitaxial source/drains). The source/drain regions 270 may also include materials and/or dopants that achieve desired tensile stress and/or compressive stress in adjacent channel regions (e.g., formed by semiconductor layers 210). As used herein, the source/drain region 270 may refer to a source of a device (e.g., a particular transistor), a drain of a device, or a source and/or a drain of multiple devices.

The portion of the CFET 200 also includes source/drain contacts, such as source/drain contacts 275, that are disposed vertically above or below the source/drain regions 270 to provide electrical connectivity to the source/drain regions 270. In some embodiments, at least some of the source/drain contacts 275 may be at least partially surrounded by barrier layers or liner layers 278.

The portion of the CFET 200 may further include conductive vias, such as conductive vias 280, that are disposed vertically above or below the source/drain contacts 275, to further provide electrical connectivity to the source/drain contacts 275, and by extension, to the source/drain regions 270. The portion of the CFET 200 may further include gate contacts, such as gate contact 285, as well as conductive vias, such as conductive via 290, that are configured to provide electrical connectivity to particular gate structures. The source/drain contacts 275, the gate contacts 285, and the conductive vias 280 and 290 may each include one or more types of conductive materials, such as tungsten, aluminum, copper, cobalt, ruthenium, and/or combinations thereof.

The portion of the CFET 200 may also include electrical isolation layers/structures that are configured to provide electrical isolation among various microelectronic components (e.g., the gate electrode layers 230 or the source/drain regions 270). For example, the portion of the CFET 200 may include an interlayer dielectric (ILD) 295 and one or more dielectric layers, such as dielectric layers 297 and 298. For example, the ILD and/or the dielectric layers 297-298 may include dielectric materials such as silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), xerogel, aerogel, amorphous fluorinated carbon, parylene, benzocyclobutene-based (BCB) material, polyimide, other dielectric material, or a combination thereof. The ILD 295 may also be surrounded by a contact etching stop layer (CESL), which may have a different material composition than the ILD 295.

The portion of the CFET 200 may also include bonding pads 299. The bonding pads 299 may include a conductive material, such as Al, Ag, Au, Cu, Co, Ir, Mo, Ni, Pt, Ru, Si, Ta, Tu, W, Zr, or a combination thereof. The bonding pads 299 may each be electrically coupled to one or more other conductive components, such as the conductive vias 280. As such, the bonding pads 299 may be utilized to provide electrical connectivity to the microelectronic components of the CFET 200, such as to the source/drain regions 270. Although not specifically illustrated herein for reasons of simplicity, it is understood that bonding pads similar to the bonding pads 299 may be implemented to provide electrical connectivity to the gate structures of the CFET 200 as well.

Other components of the CFET 200 are not specifically discussed herein for reasons of simplicity. It is also understood that in embodiments where the portion of the CFET 200 illustrated in FIG. 1D is a top tier device, then a bottom tier device that has a substantially similar or identical structure as the top tier device may be bonded to the top tier device to form the CFET. In some embodiments, the top tier device may include n-type transistors, while the bottom tier device may include p-type transistors, or vice versa. In other embodiments, the top tier device and the bottom tier device may include the same type of transistors (e.g., both including n-type transistors or both including p-type transistors).

Regardless of whether the transistors of an IC are implemented as a FinFET of FIGS. 1A-1B, as a GAA device of FIG. 1C, or as a CFET device of FIG. 1D, it is understood that they may benefit from the concepts of the present disclosure. For example, the fabrication and/or packaging of IC devices may involve one or more bonding processes. Using CFET devices as an example, a monolithic CFET architecture may fabricate a top tier device and a bottom tier device on a same wafer. However, the high aspect ratio in manufacturing monolithic CFET devices has led to process challenges related to etching, thin film, diffusion, etc. To address the challenges of monolithic CFET fabrication, hybrid bonding may be used to form a parallel CFET device, in which the top tier device corresponding to the portion of the CFET 200 shown in FIG. 1D is bonded to a bottom tier device of the CFET, which may have similar structures as the top tier device. In such a hybrid bonding process, the conductive via 280 of the top tier device of the CFET 200 may be bonded to a similar conductive via of the bottom tier device of the CFET 200, the conductive via 290 of the top tier device of the CFET 200 may be bonded to a similar conductive via of the bottom tier device of the CFET 200, and the dielectric layer 298 of the top tier device of the CFET may be bonded to a similar dielectric layer of the bottom tier device of the CFET 200.

However, bonding the conductive vias together in such a hybrid bonding process may involve a relatively high degree of alignment. If the conductive vias (e.g., the conductive via 290 of the top tier device of the CFET 200 and the corresponding conductive via from the bottom tier device of the CFET 200) are not properly aligned, then the intended electrical connection between the top tier device and the bottom tier device may be interrupted, which may lead to a malfunction (or at least a degradation) in the operations of the CFET 200. In addition, the conductive vias 280 and/or 290 may not have periodic distributions (e.g., in a planar top view). As a result, pattern uniformity may be sub-optimal, and/or the planarization of the surfaces of the bonded top and bottom tier devices may become an issue as well, which may further degrade the quality of the bonding as a part of the parallel CFET fabrication.

To address the issues discussed above, the present disclosure implements one or more bonding layers (e.g., as a part of a bonding structure) on both the top tier device and the bottom tier device of the CFET, where the hybrid bonding is achieved by bonding the bonding layers together, as discussed in more detail below.

FIGS. 2-8 collectively illustrate a series of diagrammatic fragmentary cross-sectional side views (e.g., along the X-Z plane) that correspond to a process flow to bond different IC structures together according to different embodiments of the present disclosure. For reasons of consistency and clarity, similar components appearing in FIGS. 1A-1D and FIGS. 2-8 may be labeled the same.

Referring to FIG. 2, the cross-sectional side view of a top tier device 300 of a CFET is illustrated. The top tier device 300 may be substantially similar to the top tier device of the CFET 200 discussed above with reference to FIG. 1D. However, the top tier device of the CFET 200 of FIG. 1D is flipped vertically upside down (in the Z-direction) compared to the top tier device 300 illustrated in FIG. 2. In other words, whereas the bonding pads 299 face upwards and the dielectric layer 298 face downwards in the top tier device of the CFET 200 of FIG. 1D, the bonding pads 299 face downwards and the dielectric layer 298 face upwards in the top tier device 300 of FIG. 2. Alternatively stated, a side 310 of the top tier device 300 faces upwardly in the Z-direction in FIG. 2, and a side 311 of the top tier device 300 faces downwardly in the Z-direction in FIG. 2.

As shown in FIG. 2, the top tier device 300 includes not just components of a transistor, such as channels (e.g., formed by the semiconductor layers 210), source/drain regions 270, and gates (e.g., including the gate dielectric layer 220 and gate electrode layer 230), but it also include various interconnection structures. For example, the top tier device 300 includes a back-end-of-line (BEoL) interconnection structure 320 that is located over the side 311 of the transistor components, as well as a middle-end-of-line (MEoL) interconnection structure 321 that is located over the side 310 of the transistor components.

The BEoL interconnection structure 320 may include one or more dielectric layers such as the dielectric layer 298, as well as conductive components, such as conductive vias 280 and/or the bonding pads 299 that extend at least partially through the dielectric layers vertically in the Z-direction. For example, in some embodiments, the dielectric layer 298 may be formed over the gate structures and over the source/drain contacts 275 on the side 311. One or more etching processes may then be performed to etch trenches into the dielectric layer 298, which may be filled by a one or more conductive materials via one or more deposition processes to form the conductive vias. Similarly, the bonding pads 299 may be formed by forming another dielectric layer 298 over the conductive vias 280 on the side 311, etching openings into the dielectric layer 298, and filling the etched openings with one or more conductive materials to form the bonding pads 299.

The formation of the MEoL interconnection structure 321 may involve similar processes that were used to form the BEL interconnection structure 320. For example, the ILD 295 may be formed over the side 310 of the transistor components, and etching processes may be performed to etch openings through the ILD 295, which are subsequently filled with one or more conductive materials through one or more deposition processes to form the source/drain contact 275, the conductive via, and the conductive via 290. These conductive components may be formed in different stages. For example, the source/drain contact 275 may be formed first, followed by the formation of the conductive via 280 (functioning as a source/drain via) and the formation of the conductive via 290 (functioning as a gate via). As will be discussed below in more detail, one aspect of the present disclosure involves utilizing the MEoL interconnection structure 321, rather than the BEoL interconnection structure 320, to perform a hybrid bonding process. In other words, the top tier device 300 will be bonded to a bottom tier device (discussed below) through the MEoL interconnection structure 321, not the BEoL interconnection structure 320.

A dielectric layer 330 is formed over the MEoL interconnection structure 321 on the side 310 of the top tier device 300. For example, a deposition process such as a chemical vapor deposition (CVD), a physical vapor deposition (PVD), or an atomic layer deposition (ALD) may be performed to form the dielectric layer 330 over the surfaces of the dielectric layer 298 and the conductive vias 280 and 290. In various embodiments, the dielectric layer 330 may include SiN, SiON, SiCN, SiOC, SiOCN, BN, BCN, TiO₂, TiON, TiN, AlOₓ, AlON, AlN, or a combination thereof.

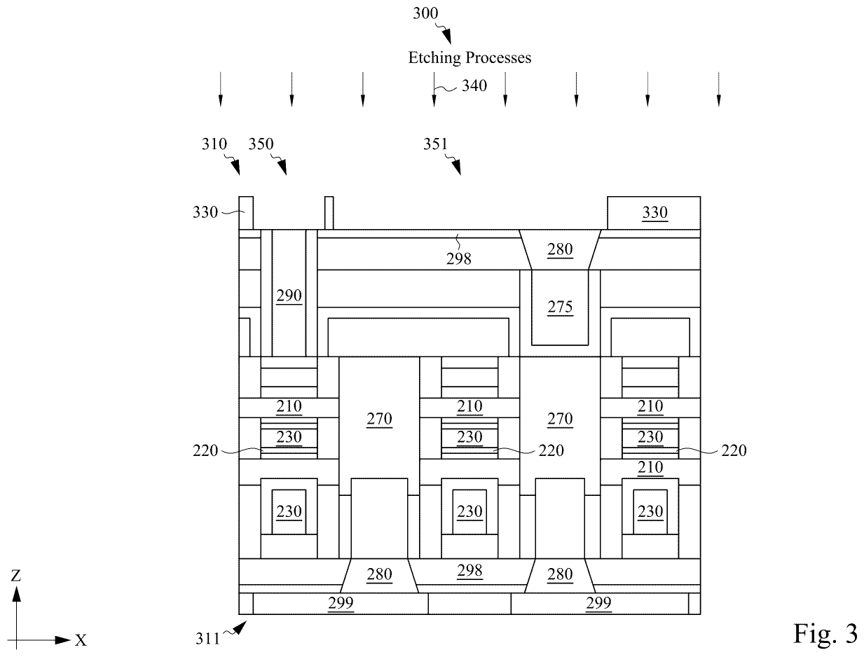

Referring now to FIG. 3, one or more etching processes 340 are performed to the top tier device 300 from the side 310 to form a plurality of openings in the dielectric layer 330, such as openings 350 and 351. For example, the one or more etching processes 340 may include one or more dry etching process in some embodiments, or one or more wet etching processes in some other embodiments, to remove portions of the dielectric layer 330. As a result, openings 350 and 351 expose the upper surfaces of the conductive vias 290 and 280, respectively, to the side 310. Note that the opening 350 may be wider than the conductive via 290 in the X-direction, which may facilitate the alignment between the conductive via 290 and a corresponding conductive via of a bottom tier device, as will be discussed below in more detail.

Also note that the openings 350 and 351 need not have the same (or even similar) dimensions in the X-direction. Instead, one can be significantly wider than the other. For example, the opening 351 can be significantly wider than the opening 350 in the X-direction. Th wider width of the opening 351 may be configured to accommodate the location of another conductive via of a bottom tier device to be bonded with the top tier device 300, which may not be aligned with the conductive via 280, as will be discussed in more detail below.

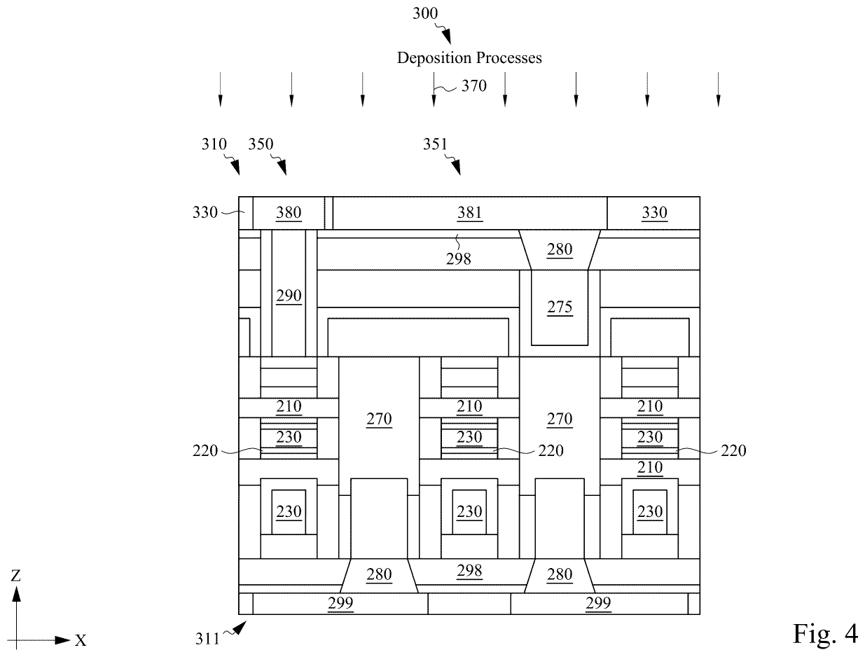

Referring now to FIG. 4, one or more deposition processes 370 may be performed to the top tier device 300 to form bonding elements 380 and 381 in the openings 350 and 351, respectively. In some embodiments, the one or more deposition processes 370 may include CVD, PVD, ALD, or a combination thereof. In some embodiments, the deposited materials may include Al, Ag, Au, Cu, Co, Ir, Mo, Ni, Pt, Ru, Si, Ta, Tu, W, Zr, or a combination thereof. Table 1 includes a list of the candidate materials for the dielectric layer 330 and the bonding elements 380-381, along with certain physical properties associated therewith:

TABLE 1

| Candidate | Candidate | | | |
|---|---|---|---|---|
| material | material for | | | Coefficient |
| for the | the bonding | Resistivity | | of thermal |
| dielectric | elements | (micro-ohm * | MP (degree | expansion |
| layer 330 | 380-381 | centimeter) | Celsius) | (10⁻⁶ * K⁻¹) |
| SiN | Al | 2.6~2.7 | 650~670 | 21~24 |
| SiON | Ag | 1.58~1.68 | 950~970 | 19~19.7 |
| SiCN | Au | 2.15~2.25 | 1060~1070 | 14~14.4 |
| SiOC | Cu | 1.7~1.74 | 1080~1090 | 16~16.7 |
| SiOCN | Co | 5.9~6.1 | 1490~1500 | 11.5~12.5 |
| BN | Ir | 4.6~4.8 | 2460~2470 | 6~7 |
| BCN | Mo | 5.4~5.6 | 2620~2630 | 4.5~5.5 |
| TiO2 | Ni | 7.1~7.3 | 1450~1460 | 12.5~13.5 |
| TiON | Pt | 10.5~10.7 | 1760~1775 | 8.5~9.5 |
| AlOx | Ru | 7~7.2 | 2330~2340 | 8.5~9.5 |
| AlON | Si | | 1405~1415 | 3~5 |
| AlN | Ta | 13~13.2 | 3010~3030 | 6~7 |
| | Ti | 39~41 | 1935~1945 | 8.5~9 |
| | W | 5.3~5.5 | 3410~3430 | 4~5 |
| | Zr | 43~43.6 | 2120~2135 | 5~6.2 |

It is understood that a planarization process, such as a CMP process, may be performed to the deposited materials to planarize the upper surfaces of the bonding elements 380 and 381 and the dielectric layer 330, for example, until the upper surfaces of the bonding elements 380-381 are substantially coplanar with the upper surfaces of the dielectric layer 330. It is also understood that in some embodiments, the one or more deposition processes 370 may also form liners (e.g., as a barrier layer) around the bonding elements 380 and 381. For reasons of simplicity, however, the liner layers are not specifically illustrated herein. It is understood that the dielectric layer 330 and the bonding elements 380-381 may also be considered a part of the MEoL interconnection structure 321 of the top tier device 300.

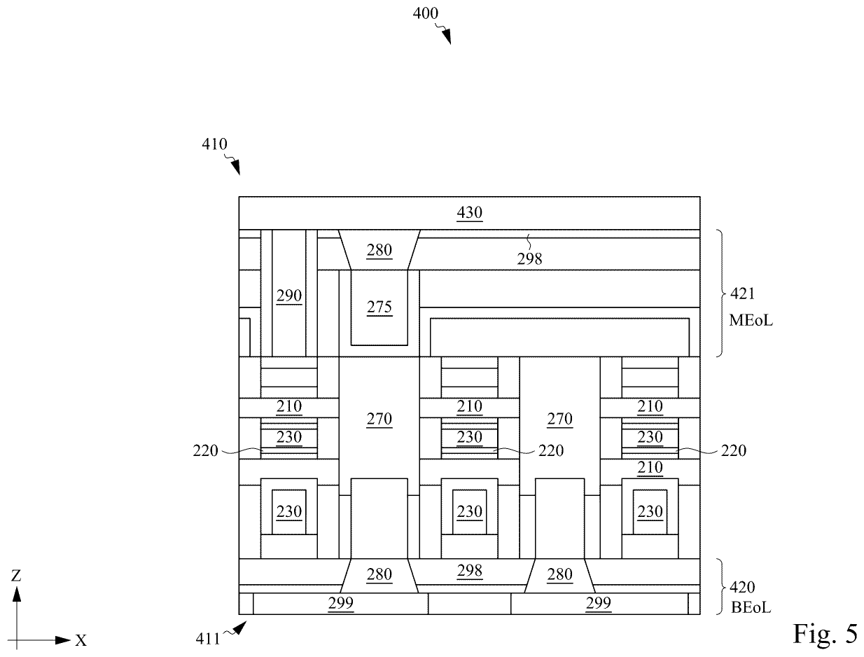

Referring to FIG. 5, the cross-sectional side view of a bottom tier device 400 of the CFET is illustrated. The bottom tier device 400 may be structurally similar to the top tier device 300 discussed above with reference to FIGS. 2-4. However, the transistors of the top tier device 300 and the transistors of the bottom tier device 400 have different types of conductivity in some embodiments. For example, the top tier device 300 may include n-type transistors, while the bottom tier device 400 may include p-type transistors in some embodiments. In addition, the location of various microelectronic components may be different in the top tier device 300 and the bottom tier device 400. For example, the conductive via 280 (e.g., a source/drain via) and the conductive via 290 (e.g., a gate via) may be spaced relatively far apart in the X-direction in the top tier device 300. In comparison, the conductive via 280 (e.g., a source/drain via) and the conductive via 290 (e.g., a gate via) may be located much closer to each another in the X-direction in the bottom tier device 400.

As shown in FIG. 5, the bonding pads 299 of the bottom tier device 400 face downwards, and the dielectric layer 298 face upwards. Alternatively stated, a side 410 of the bottom tier device 400 faces upwardly in the Z-direction in FIG. 5, and a side 411 of the bottom tier device 400 faces downwardly in the Z-direction in FIG. 5. Similar to the top tier device 300 discussed above, the bottom tier device 400 also includes a BEoL interconnection structure 420 and an MEoL interconnection structure 421. The BEoL interconnection structure 420 is located over the side 411 of the transistor components of the bottom tier device 400, and the MEoL interconnection structure 421 is located over the side 410 of the transistor components of the bottom tier device 400. And similar to the top tier device 300, the formation of the BEoL interconnection structure 420 and the MEoL 421 interconnection structure for the bottom tier device 400 may also include various deposition processes for forming dielectric layers, etching processes for etching trenches into the dielectric layers, and filling the trenches with conductive materials to form the various conductive components, such as the conductive vias 280 and the bonding pads of the BEoL interconnection structure 420, and the source/drain contact 275, the conductive via 280, and the conductive via 290 of the MEoL interconnection structure 421. Again, one aspect of the present disclosure involves bonding the bottom tier device 400 to the top tier device 300 through the MEoL interconnection structure 421, rather than through the BEoL interconnection structure 420.

A dielectric layer 430 is formed over the MEoL interconnection structure 421 on the side 410 of the bottom tier device 400. For example, a deposition process such as CVD, PVD, or ALD may be performed to form the dielectric layer 430 over the surfaces of the dielectric layer 298 and the conductive vias 280 and 290. In various embodiments, the dielectric layer 430 may include SiN, SiON, SiCN, SiOC, SiOCN, BN, BCN, TiO₂, TiON, TiN, AlOₓ, AlON, AlN, or a combination thereof. In some embodiments, the list of materials may include the same materials for the dielectric layer 330 listed in table 1 above. In some embodiments, the dielectric layer 430 formed on the bottom tier device 400 may have a same dielectric material composition as the dielectric layer 330 formed on the top tier device 300.

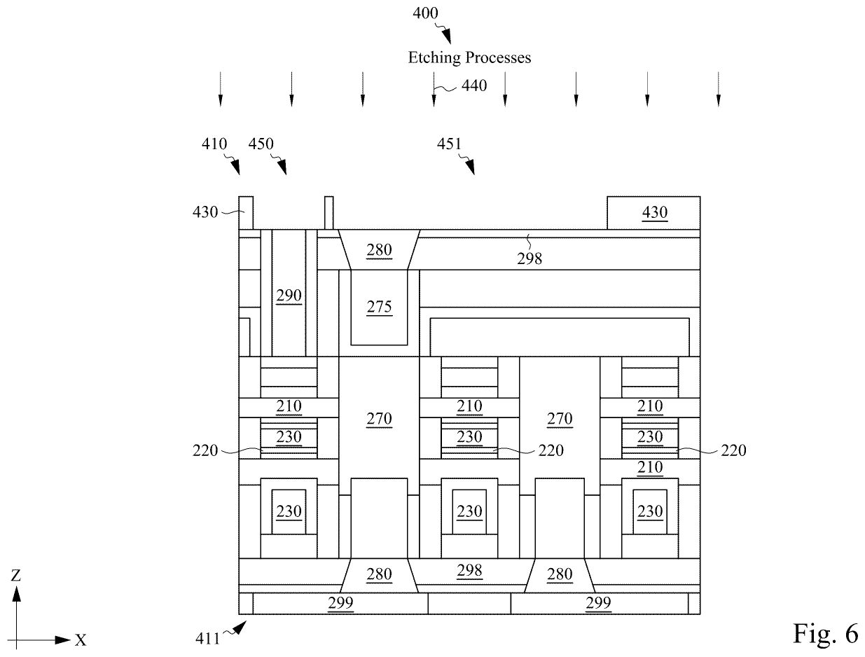

Referring now to FIG. 6, one or more etching processes 440 are performed to the bottom tier device 400 from the side 410 to form a plurality of openings in the dielectric layer 430, such as openings 450 and 451. For example, the one or more etching processes 440 may include one or more dry etching process in some embodiments, or one or more wet etching processes in some other embodiments, to remove portions of the dielectric layer 430. As a result, openings 450 and 451 expose the upper surfaces of the conductive vias 290 and 280, respectively, to the side 410. Note that the opening 450 may be wider than the conductive via 290 in the X-direction, which may facilitate the alignment between the conductive via 290 and the conductive via of the bottom tier device 400 of FIG. 5, as will be discussed below in more detail.

Also note that the openings 450 and 451 need not have the same (or even similar) dimensions in the X-direction. Instead, one can be significantly wider than the other. For example, the opening 451 can be significantly wider than the opening 450 in the X-direction. The wider width of the opening 451 may be configured to accommodate the location of the conductive via 280 of the top tier device 300 (see FIG. 4), which will be bonded with the bottom tier device 400 in a subsequent process.

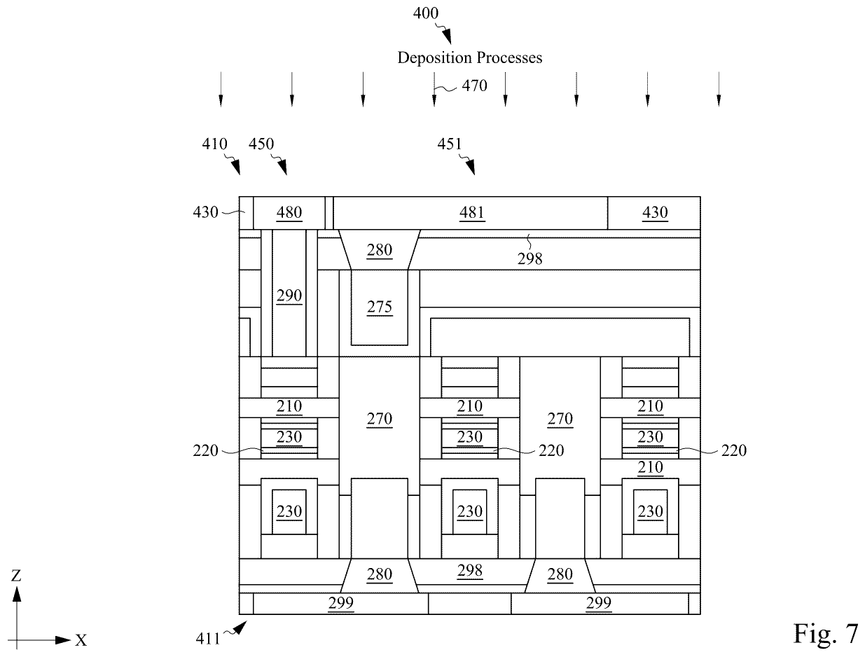

Referring now to FIG. 7, one or more deposition processes 470 may be performed to the bottom tier device 400 to form bonding elements 480 and 481 in the openings 450 and 451, respectively. In some embodiments, the one or more deposition processes 470 may include CVD, PVD, ALD, or a combination thereof. In some embodiments, the deposited materials may include Al, Ag, Au, Cu, Co, Ir, Mo, Ni, Pt, Ru, Si, Ta, Tu, W, Zr, or a combination thereof. In some embodiments, the deposited materials may include the candidate material for the bonding elements listed in Table 1 above. In some embodiments, the deposited materials that form the bonding elements 480 and 481 of the bottom tier device 400 have a same material composition as the bonding elements 380 and 381 of the top tier device 300. It is understood that a planarization process, such as a CMP process, may be performed to the deposited materials to planarize the upper surfaces of the bonding elements 480 and 481 and the dielectric layer 430, for example, until the upper surfaces of the bonding elements 480-481 are substantially coplanar with the upper surfaces of the dielectric layer 430. It is also understood that in some embodiments, the one or more deposition processes 470 may also form liners (e.g., as a barrier layer) around the bonding elements 480 and 481. For reasons of simplicity, however, the liner layers are not specifically illustrated herein. It is understood that the dielectric layer 430 and the bonding elements 480-481 may also be considered a part of the MEoL interconnection structure 421 of the bottom tier device 400.

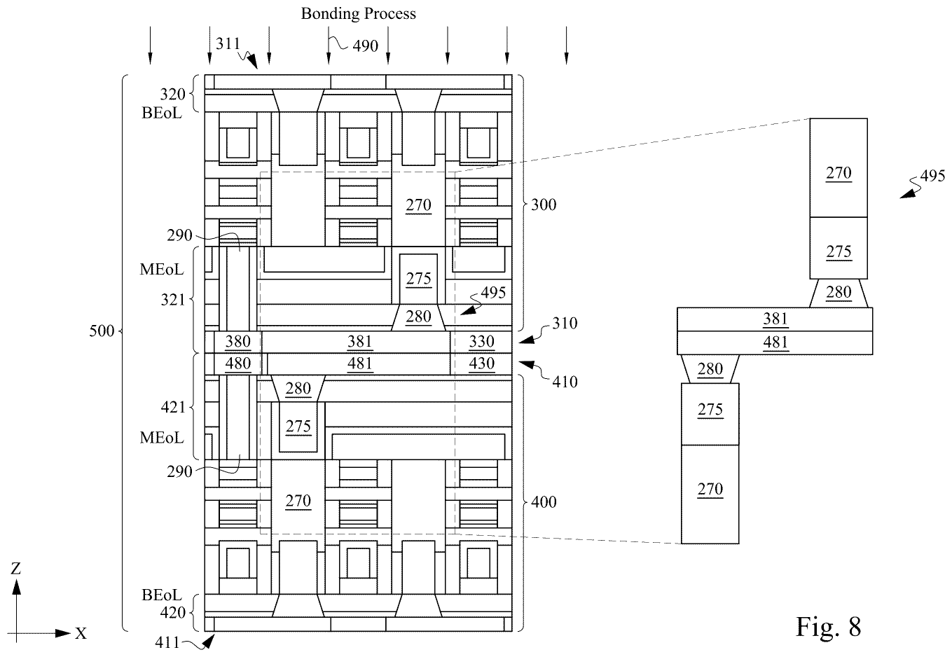

Referring now to FIG. 8, a bonding process 490 is performed to bond the top tier device 300 and the bottom tier device 400 together to form a parallel CFET device 500. As a part of the bonding process 490, the top tier device 300 is flipped vertically upside down, such that the side 310 (facing upwards in FIG. 5) is facing downwards in FIG. 8 (e.g., facing the bottom tier device 400). At this point, the MEoL interconnection structure 321 of the top tier device 300 is now facing the MEoL interconnection structure 421 of the bottom tier device 400.

The dielectric layers 330 and 430 are then bonded together, as are the bonding elements 380-480, and the bonding elements 381-481. The bonding of the bonding elements 380 and 480 establishes an electrical connection between the conductive vias 290 of the top tier device 300 and the conductive via 290 of the bottom tier device 400, and the bonding of the bonding elements 381 and 481 establishes an electrical connection between the conductive vias 280 of the top tier device 300 and the conductive via 280 of the bottom tier device 400. In this manner, the top tier device 300 and the bottom tier device 400 are electrically coupled together. Note that since the dielectric layer 330 and the bonding elements 380-381 may be considered a part of the MEoL interconnection structure 321 of the top tier device 300, and that the dielectric layer 430 and the bonding elements 480-481 may be considered a part of the MEoL interconnection structure 421 of the bottom tier device 400, it may be said that the top tier device 300 and the bottom tier device 400 are bonded together via their respective MEoL interconnection structures 321 and 421, rather than through their BEoL interconnection structures 320 and 420.

Note that FIG. 8 also illustrates a magnified cross-sectional side view of a portion 495 of the top tier device 300 and the bottom tier device 400 that are bonded together. The magnified view includes the source/drain regions 270, the source/drain contacts 275, and the conductive vias 280 of the top tier device 300 and the bottom tier device 400, as well as the bonding elements 381 and 481, so as to provide better visual clarity of how the bonding scheme of the present disclosure is implemented. Other components are not specifically illustrated in the magnified view for reasons of simplicity.

The bonding scheme of the present disclosure offers inherent advantages. For example, had the top tier device 300 been bonded to the bottom tier device 400 without the bonding structure (comprised of the dielectric layers 330 and 430 and the bonding elements 380-381 and 480-481) in between, the alignment between the various components of the top tier device 300 and the bottom tier device 400 could become a problem. As shown in FIG. 8, there is a significant lateral offset in the X-direction between the conductive via 280 of the top tier device 300 and the conductive via 280 of the bottom tier device 400. Such a lateral offset could be due to IC design, or it may be a result of suboptimal fabrication processing that occurred prior to the bonding process 490. In any case, the lateral offset between these conductive vias 280 makes their bonding (and the intended electrical connection) difficult or even impossible in some cases.

Here, the implementation of the bonding elements 381 and 481 can accommodate the lateral offset between the conductive vias 280. In other words, the bonding element 381 is sufficiently long such that its “right” portion (as viewed in FIG. 8) can extend to, and be in electrical contact with, the bottom surface of the conductive via 280 of the top tier device 300. Meanwhile, the bonding element 481 is sufficiently long such that its “left” portion can extend to, and be in electrical contact with, the top surface of the conductive via 280 of the bottom tier device 400. Since the bonding elements 381 and 481 are substantially wider than the corresponding conductive vias 280 to which they are electrically coupled, there is inherently a greater margin for error in the bonding of the bonding elements 381 and 481. In other words, even if the bonding elements 381 and 481 are not perfectly aligned vertically, their sheer sizes inherently makes it very likely that at least a portion of the bonding element 381 will come into electrical and physical contact with another portion of the bonding element 481, which then allows the electrical connection between the conductive vias 280 of the top tier device 300 and the bottom tier device 400 to be established.

The advantages discussed above may also be applied to the bonding elements 380 and 480, albeit to a lesser extent. For example, since the openings 350 (see FIG. 3) and 450 (see FIG. 6) are formed to be wider than the conductive vias 290 of the top tier device 300 and the bottom tier device 400, respectively, the bonding elements 380 and 480 filling these openings 350 and 450 are also wider (in the X-direction) than the conductive vias 290 of the top tier device 300 and the bottom tier device 400, respectively. As such, the margin for aligning the bonding elements 380 and 480 together is still greater than aligning the conductive vias 290 of the top tier device 300 and the bottom tier device 400 together. In other words, whereas a sufficiently big lateral offset between the conductive vias 290 could lead to an electrical discontinuity between them, the same amount of lateral offset may still allow the bonding elements 380 and 480 to be bonded together and establish physical and electrical contact with one another, which in turn establishes electrical connectivity between the conductive vias 290 of the top tier device 300 and the bottom tier device 400.

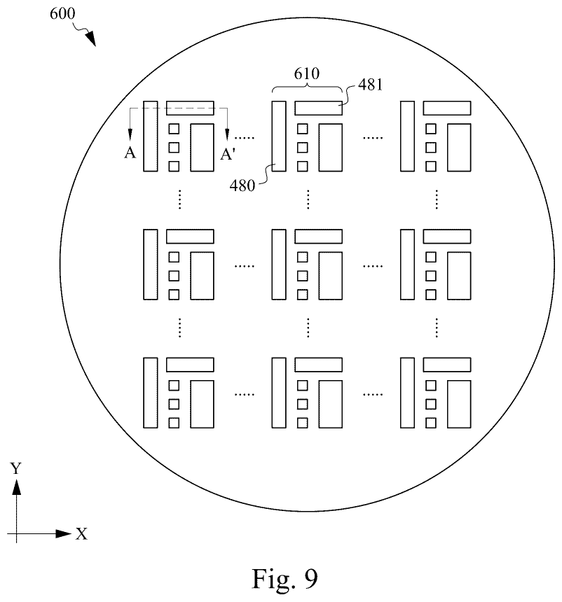

FIG. 9 illustrates a top view of an example wafer 600 on which a plurality of IC dies 610 is implemented. The top view is defined by an X-direction and a Y-direction that is perpendicular to the X-direction. The IC dies 610 are arranged in a plurality of rows along the X-direction and a plurality columns along the Y-direction. Although each row and each column in FIG. 9 includes three of such IC dies 610, it is understood that this is done merely for the sake of simplicity, and that each row and each column may include a significantly greater number of IC dies 610.

In some embodiments, each IC die 610 may include the parallel CFET device 500, which as discussed above, is formed by bonding the top tier device 300 and the bottom tier device 400 together. For example, a cutline A-A′ is illustrated across one of the IC dies 610, and it is understood that the cross-sectional side view of FIG. 8 may be obtained corresponding to such a cutline A-A′. It is also understood that the planar top view may be obtained along a horizontal plane that cuts across (e.g., intersects with) the bonding elements 480 and 481. In other words, the geometric patterns shown in FIG. 9 may include the top views of the bonding elements 480-481, as well as other bonding elements that do not specifically appear in the cross-sectional view of FIG. 8. Lastly, it is understood that the top view of the bonding elements 380 and 381 (and the other bonding elements in that bonding layer) may appear substantially similar to that of FIG. 9. In other words, the top view of the bonding layer for the top tier device 300 may appear substantially similar to the top view of the bonding layer for the bottom tier device 400.

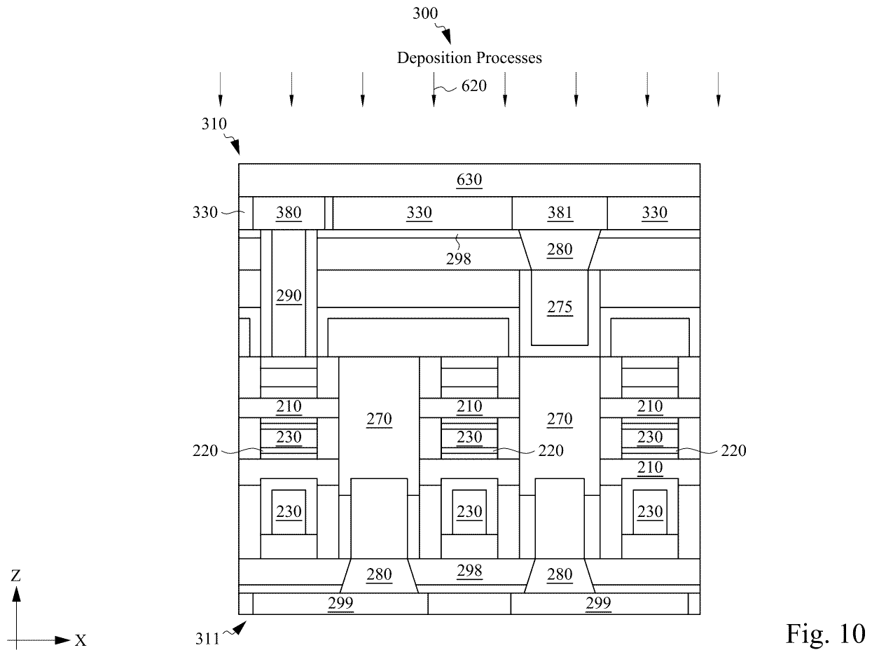

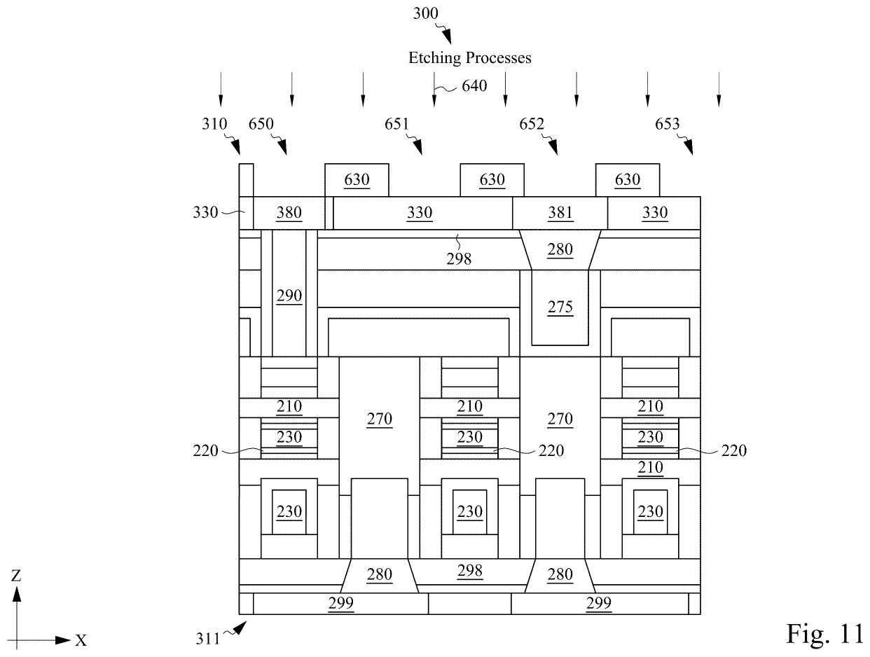

The fabrication process flow discussed above in association with FIGS. 2-9 corresponds to a first embodiment of the present disclosure. FIGS. 10-17 and the discussions below describe a second embodiment of the present disclosure. Again, for reasons of consistency and clarity, similar components appearing in the first embodiment will be labeled the same in the second embodiment.

Referring now to FIG. 10, the second embodiment of the present disclosure may also form the bonding structure that includes the dielectric layer 330 and the bonding elements 380-381 embedded in the dielectric layer 330 over the top tier device 300. However, the bonding element 381 may be substantially narrower in the second embodiment of FIG. 10. For example, although the bonding element 381 may still be wider than the conductive via 280 over which it is formed, the bonding element 381 in FIG. 10 may not be as wide as the bonding element 381 in the embodiment of FIG. 5.

A deposition process 620 is performed to form a dielectric layer 630 over the dielectric layer 330 and the bonding elements 380-381. In some embodiments, the deposition process 620 may include CVD, PVD, ALD, or combinations thereof, and the material composition of the dielectric layer 630 may be substantially similar to that of the dielectric layer 330. For example, in embodiments where the dielectric layer 330 includes SiN, SiON, SiCN, SiOC, SiOCN, BN, BCN, TiO₂, TiON, TiN, AlOₓ, AlON, AlN, the dielectric layer 630 may include SiN, SiON, SiCN, SiOC, SiOCN, BN, BCN, TiO₂, TiON, TiN, AlOₓ, AlON, AlN as well.

Referring now to FIG. 11, one or more etching processes 640 are performed to etch openings in the dielectric layer 630 from the side 310. In some embodiments, the one or more etching processes 640 may include one or more dry etching processes or one or more wet etching processes, to remove portions of the dielectric layer 630. As a result of the etching processes 640, openings 650, 651, 652, and 653 are formed. The opening 650 exposes an upper surface of the bonding element 380, the opening 651 exposes a portion of an upper surface of the dielectric layer 330, the opening 652 exposes an upper surface of the bonding element 381, and the opening 653 exposes another portion of the upper surface of the dielectric layer 330. In some embodiments, the openings 650-653 have substantially identical widths in the X-direction, and they are spaced apart from one another by substantially identical distances in the X-direction (and in a perpendicular Y-direction not directly visible in FIG. 11). In this manner, the openings 650-653 may be said to have a periodic distribution.

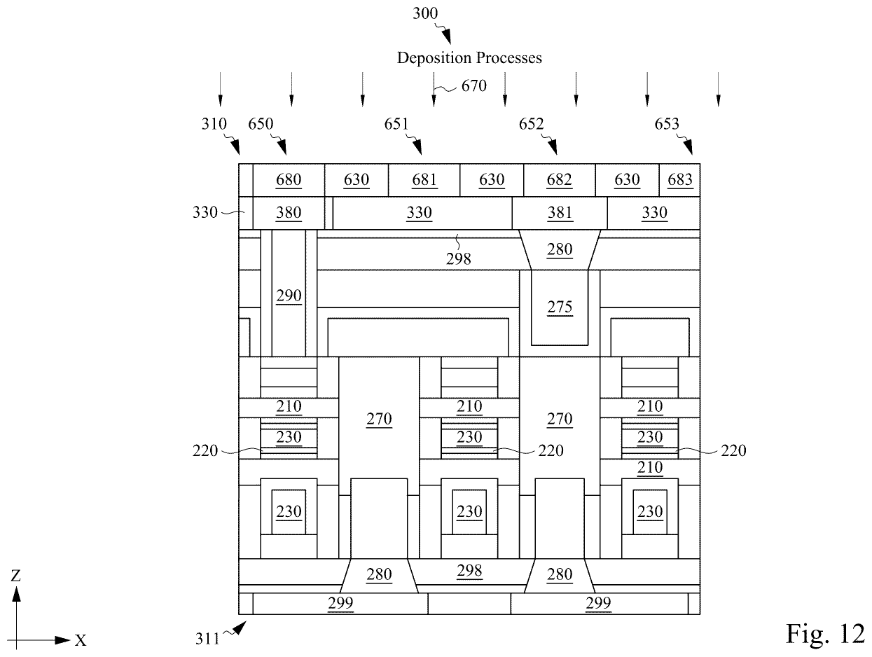

Referring now to FIG. 12, one or more deposition processes 670 may be performed to form bonding elements 680-683 in the openings 650-653, respectively. In some embodiments, the one or more deposition processes 670 may include CVD, PVD, ALD, or a combination thereof. In some embodiments, the deposited materials may include Al, Ag, Au, Cu, Co, Ir, Mo, Ni, Pt, Ru, Si, Ta, Tu, W, Zr, or a combination thereof. In some embodiments, the deposited materials that form the bonding elements 680-683 have a same material composition as the bonding elements 380-381. A planarization process, such as a CMP process, may also be performed to the deposited materials to planarize the upper surfaces of the bonding elements 680-683 and the dielectric layer 630, for example, until the upper surfaces of the bonding elements 680-683 are substantially coplanar with the upper surfaces of the dielectric layer 630. It is also understood that in some embodiments, the one or more deposition processes 670 may also form liners (e.g., as a barrier layer) around each of the bonding elements 680-683. For reasons of simplicity, however, the liner layers are not specifically illustrated herein.

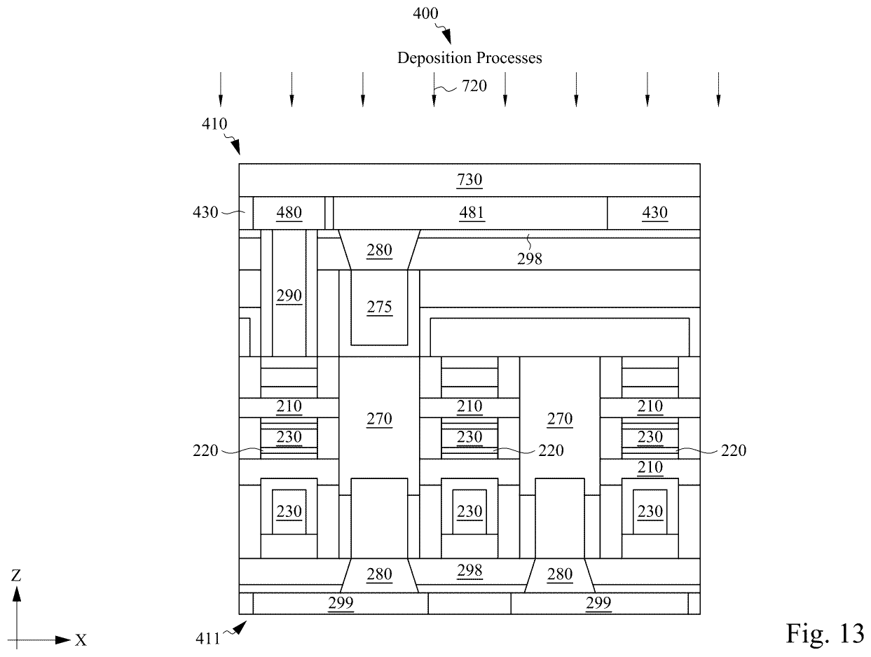

Referring now to FIG. 13, the second embodiment of the present disclosure may also form the bonding structure that includes the dielectric layer 430 and the bonding elements 480-481 embedded in the dielectric layer 430 over the bottom tier device 400. A deposition process 720 is performed to form a dielectric layer 630 over the dielectric layer 430 and the bonding elements 480-481. In some embodiments, the deposition process 720 may include CVD, PVD, ALD, or combinations thereof, and the material composition of the dielectric layer 730 may be substantially similar to that of the dielectric layer 430. For example, in embodiments where the dielectric layer 430 includes SiN, SiON, SiCN, SiOC, SiOCN, BN, BCN, TiO₂, TiON, TiN, AlOₓ, AlON, AlN, the dielectric material layer may include SiN, SiON, SiCN, SiOC, SiOCN, BN, BCN, TiO₂, TiON, TiN, AlOₓ, AlON, AlN as well. In some embodiments, the dielectric layer 430 may include the candidate material for the dielectric layer 330 listed in Table 1 above.

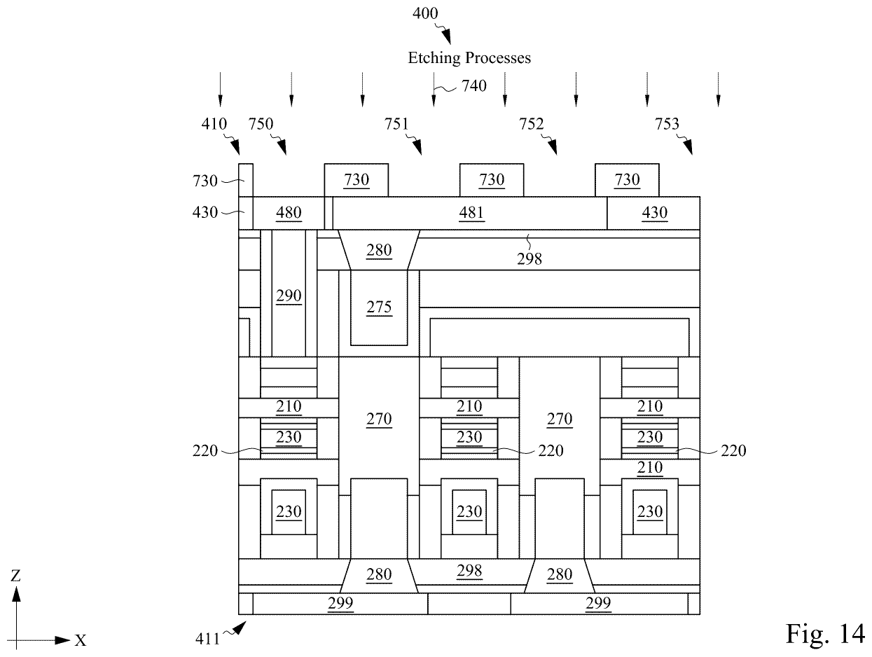

Referring now to FIG. 14, one or more etching processes 740 are performed to etch openings in the dielectric layer 730 from the side 410. In some embodiments, the one or more etching processes 740 may include one or more dry etching processes or one or more wet etching processes, to remove portions of the dielectric layer 730. As a result of the etching processes 740, openings 750, 751, 752, and 753 are formed. The opening 750 exposes an upper surface of the bonding element 480, the opening 751 exposes a portion of an upper surface of the bonding element 481, the opening 752 exposes another portion of an upper surface of the bonding element 481, and the opening 753 exposes a portion of an upper surface of the dielectric layer 730. In some embodiments, the openings 750-753 have substantially identical widths in the X-direction, and they are spaced apart from one another by substantially identical distances in the X-direction (and in a perpendicular Y-direction not directly visible in FIG. 11). In this manner, the openings 750-753 may be said to have a periodic distribution.

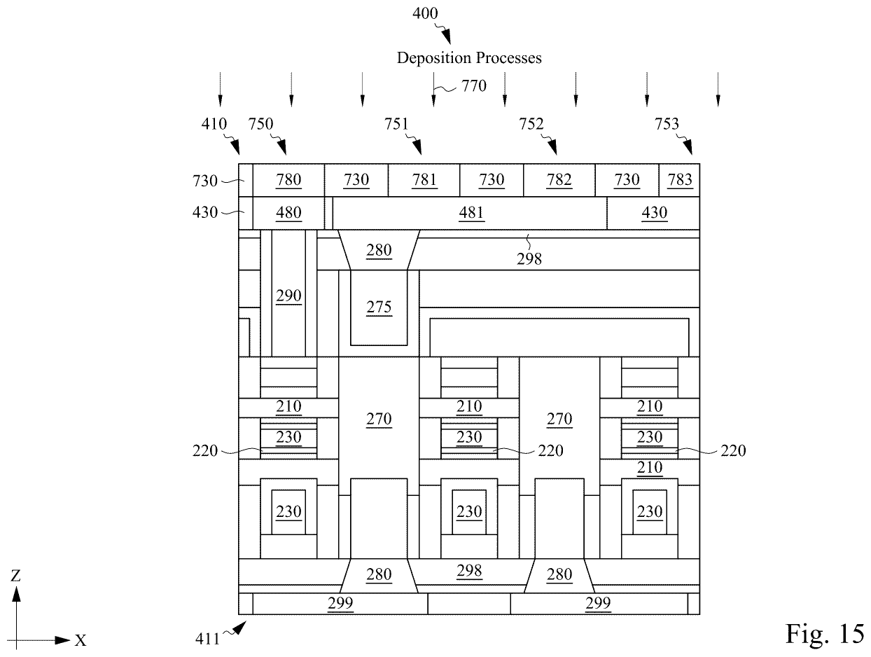

Referring now to FIG. 15, one or more deposition processes 770 may be performed to form bonding elements 780-783 in the openings 750-753, respectively. In some embodiments, the one or more deposition processes 770 may include CVD, PVD, ALD, or a combination thereof. In some embodiments, the deposited materials may include Al, Ag, Au, Cu, Co, Ir, Mo, Ni, Pt, Ru, Si, Ta, Tu, W, Zr, or a combination thereof. In some embodiments, the deposited materials that form the bonding elements 780-783 have a same material composition as the bonding elements 480-481. A planarization process, such as a CMP process, may also be performed to the deposited materials to planarize the upper surfaces of the bonding elements 780-783 and the dielectric layer 730, for example, until the upper surfaces of the bonding elements 780-783 are substantially coplanar with the upper surfaces of the dielectric layer 730. It is also understood that in some embodiments, the one or more deposition processes 770 may also form liners (e.g., as a barrier layer) around each of the bonding elements 780-783. For reasons of simplicity, however, the liner layers are not specifically illustrated herein.

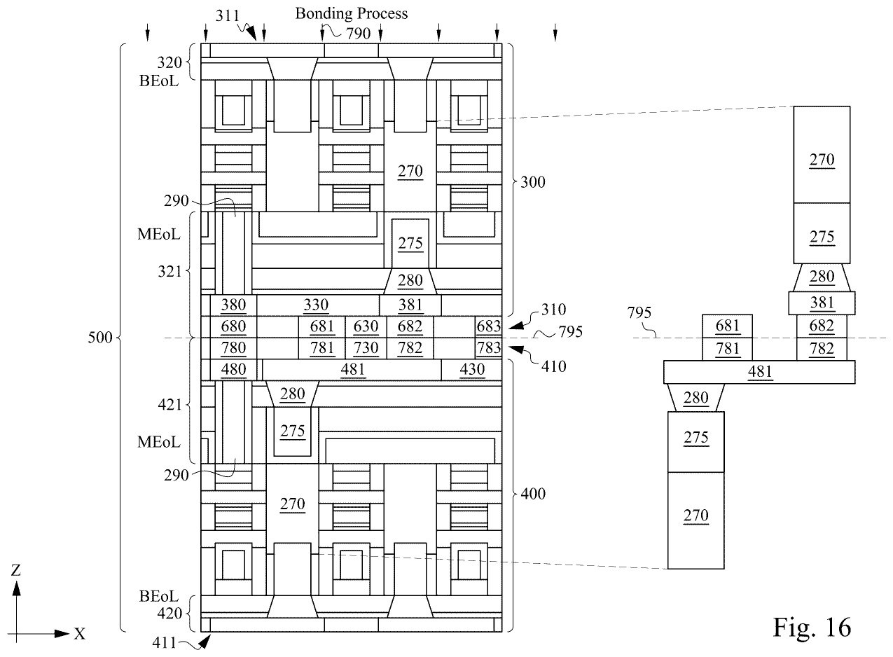

Referring now to FIG. 16, a bonding process 790 is performed to bond the top tier device 300 and the bottom tier device 400 together to form the parallel CFET device 500 according to the second embodiment of the present disclosure. As a part of the bonding process 790, the top tier device 300 is flipped vertically upside down, such that the side 310 is facing downwards in FIG. 16. At this point, the MEoL interconnection structure 321 of the top tier device 300 is now facing the MEoL interconnection structure 421 of the bottom tier device 400. The dielectric layers 630 and 730 are then bonded together, as are the bonding elements 680 and 780, 681 and 781, 682 and 782, and 683 and 783. The bonding of the bonding elements 680 and 780 establishes an electrical connection between the conductive vias 290 of the top tier device 300 and the conductive via 290 of the bottom tier device 400, and the bonding of the bonding elements 682 and 782 establishes an electrical connection between the conductive vias 280 of the top tier device 300 and the conductive via 280 of the bottom tier device 400. In this manner, the top tier device 300 and the bottom tier device 400 are electrically coupled together.

Note that the dielectric layers 330 and 630 and the bonding elements 380-381 and 680-683 may also be considered a part of the MEoL interconnection structure 321 of the top tier device 300, and the dielectric layers 430 and 730 and the bonding elements 480-481 and 780-783 may also be considered a part of the MEoL interconnection structure 421 of the bottom tier device 400. As such, it may be said that the top tier device 300 and the bottom tier device 400 are bonded together via their respective MEoL interconnection structures 321 and 421, rather than through their BEoL interconnection structures 320 and 420.

Meanwhile, the bonding elements 681, 683, 781, and 783 are considered dummy conductive components, as these bonding elements 681, 683, 781, and 783 do not establish electrical connections between the microelectronic components of the top tier device 300 and the bottom tier device 400. For example, although the bonding elements 681 and 781 are collectively coupled to the conductive via 280 through the bonding elements 481, they are not electrically coupled to any microelectronic components of the top tier device 300, since the bonding elements 681 and 781 are coupled to the dielectric layer 330, which is an insulative material. As for the bonding elements 683 and 783, they are collectively located between the dielectric layer 330 and the dielectric layer 430, which are both insulative materials. As such, the bonding elements 683 and 783 do not serve as conductive components that help establish electrical connections between the top tier device 300 and bottom tier device either.

According to various aspects of the present disclosure, the bonding elements 681, 683, 781, and 783 (e.g., the dummy bonding elements) are implemented not to establish electrical connections, but to improve the bonding process 790 itself. In more detail, some of the challenges of performing the bonding process 790 may involve the planarity of a bonding interface 795 between the top tier device 300 and the bottom tier device 400. The bonding interface 795 is defined by the surfaces of the dielectric layer 630 and the bonding elements 680-683 facing downwards, as well as by the surfaces of the dielectric layer 730 and the bonding elements 780-783 facing upwards. The planarity (e.g., how flat it is) of these surfaces is defined by the planarization processes (e.g., CMP processes) performed to the top tier device 300 after the bonding elements 680-683 are formed to fill in the openings 650-653, and also by the planarization processes (e.g., CMP processes) performed to the bottom tier device 400 after the bonding elements 780-783 are formed to fill in the openings 750-753. Any curvature or topography variation of these surfaces will contribute to the non-planarity of the bonding interface 795 (which is defined by these surfaces). The bonding of the top tier device 300 and the bottom tier device 400 may become more difficult as the non-planarity of the bonding interface 795 increases. Unfortunately, the planarization processes may be adversely affected by factors such as pattern uniformity, and the lack of pattern uniformity could lead to a dishing effect, which may cause the resulting surfaces to exhibit the curvature or topography variations that contribute to the non-planarity of the bonding interface 795.

According to various aspects of the present disclosure, the manner in which the bonding elements 680-683 and 780-783 (including the dummy bonding elements 681, 683, 781, and 783) is implemented helps to improve the planarity of the bonding interface 795. As discussed above, the openings 650-653 and 750-753 are formed to have a periodic distribution. As such, the bonding elements 680-683 and 780-783 inherently have a periodic distribution as well. For example, the bonding elements 680-683 and 780-783 may have substantially equal dimensions as one another and are spaced apart from one another by substantially equal distances as well. In this manner, the pattern uniformity (e.g., with the conductive elements 680-683 and 780-783 serving as patterns) is enhanced, which minimizes the dishing effect (or other imperfections of the planarization processes that are associated with a lack of pattern uniformity).

It is also noted that the implementation of the dummy bonding elements 681, 683, 781, and 783 further improves the planarity of the bonding interface 795. For example, had the dummy bonding elements 681, 683, 781, and 783 not been implemented, there would have been a greater amount of separation between the adjacent bonding elements 680 and 682, as well as between the adjacent bonding elements 780 and 782. Such a long separation may degrade the quality of the pattern uniformity, particularly as the length of the separation increases. In other words, if only a few functional bonding elements (such as the bonding elements 680, 682, 780, and 782) are implemented to be sparsely distributed within the bonding structure, the pattern density may be too low, which may be viewed as contributing to the pattern non-uniformity. Here, by adding the dummy bonding elements 681, 683, 781, and 783 to the overall bonding structure, the pattern density is enhanced, which in turn may contribute to the pattern uniformity and may further diminish the dishing effect of the planarization processes. Consequently, the bonding interface 795 can be made to have a greater planarity, which further enhances the quality of the bonding of the top tier device 300 and the bottom tier device 400.

Note that FIG. 8 also illustrates a magnified cross-sectional side view of a portion 495 of the top tier device 300 and the bottom tier device 400 that are bonded together. The magnified view includes the source/drain regions 270, the source/drain contacts 275, and the conductive vias 280 of the top tier device 300 and the bottom tier device 400, as well as the bonding elements 381 and 481, so as to provide better visual clarity of how the bonding scheme of the present disclosure is implemented. Other components are not specifically illustrated in the magnified view for reasons of simplicity.

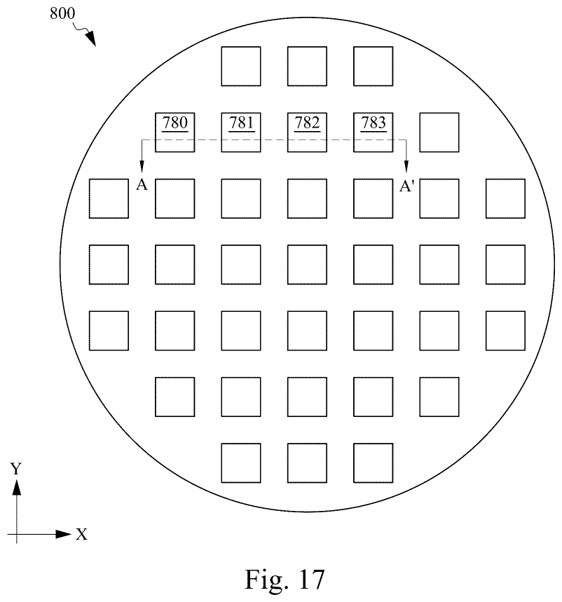

FIG. 17 illustrates a top view of an example wafer 800 on which a plurality of IC dies is implemented. The top view is defined by an X-direction and a Y-direction that is perpendicular to the X-direction. In some embodiments, each IC die may include the parallel CFET device 500, which (as discussed above) is formed by bonding the top tier device 300 and the bottom tier device 400 together according to the second embodiment. For reasons of simplicity, the IC dies are not individually illustrated in FIG. 17. Instead, the top view of FIG. 17 illustrates the periodic distribution of the bonding elements, such as bonding elements 780-783, according to an embodiment. For example, the bonding elements 780-783 may have substantially equal dimensions as one another, and they are spaced from adjacent bonding elements 780-783 by substantially equal distances.

A cutline A-A′ is illustrated across a portion of the example wafer 800 in FIG. 17, and it is understood that the cross-sectional side view of FIG. 16 may be obtained corresponding to such a cutline A-A′. It is also understood that the planar top view may be obtained along a horizontal plane that cuts across (e.g., intersects with) the bonding elements 780-783 as well. In other words, the geometric patterns shown in FIG. 17 may include the top views of the bonding elements 780-783, as well as other bonding elements that do not specifically appear in the cross-sectional view of FIG. 16. Lastly, it is understood that the top view of the bonding elements 680-683 (and the other bonding elements in that bonding layer) may appear substantially similar to that of FIG. 17. In other words, the top view of the bonding layer for the top tier device 300 may appear substantially similar to the top view of the bonding layer for the bottom tier device 400.

Note that for reasons of simplicity, the outline or boundary of each IC die is not specifically illustrated in FIG. 17. Instead, FIG. 17 illustrates the geometric shapes and distribution patterns of the bonding elements, such as bonding elements 780-783. It is also understood that the actual wafer 800 may include a far greater number of the bonding elements than what is illustrated in FIG. 17, but that is also not specifically illustrated herein for reasons of simplicity.

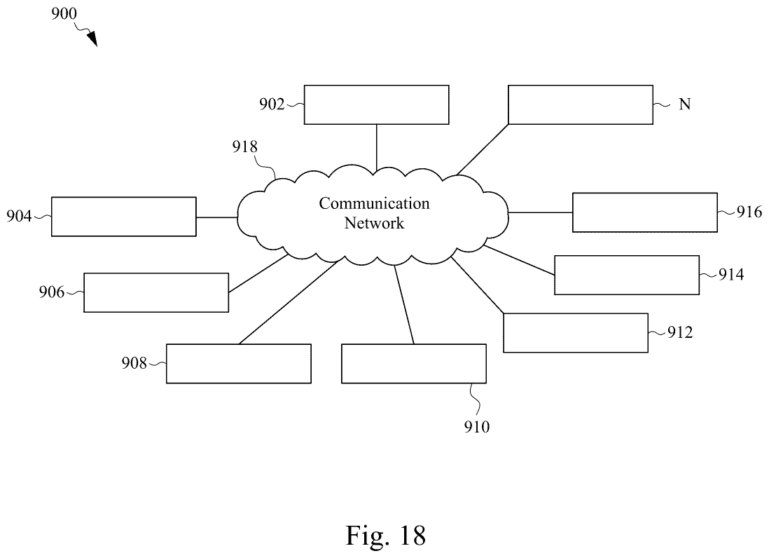

FIG. 18 illustrates an integrated circuit fabrication system 900 that may be used to perform the fabrication processes discussed above with reference to FIGS. 1-17 (e.g., to fabricate and bond the parallel CFET), according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes or a bonding tool for bonding different IC structures together; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

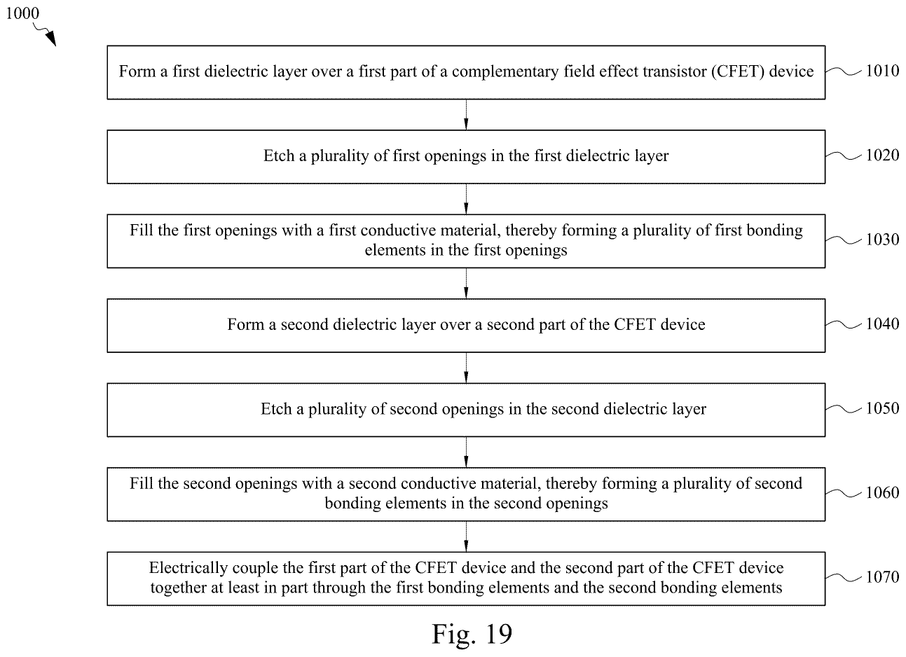

FIG. 19 is a flowchart of a method 1000 of bonding IC devices according to various aspects of the present disclosure. The method 1000 includes a step 1010 to form a first dielectric layer over a first part of a complementary field effect transistor (CFET) device.

The method 1000 includes a step 1020 to etch a plurality of first openings in the first dielectric layer

The method 1000 includes a step 1030 to fill the first openings with a first conductive material, thereby forming a plurality of first bonding elements in the first openings.

The method 1000 includes a step 1040 to form a second dielectric layer over a second part of the CFET device.

The method 1000 includes a step 1050 to etch a plurality of second openings in the second dielectric layer. In some embodiments, the first openings and the second openings are etched in a manner such that each of the first openings is vertically aligned with a respective one of the second openings in a cross-sectional side view. In some embodiments, the first openings and the second openings are etched in a manner such that the first openings and the second openings each have a periodic distribution in a top view.

The method 1000 includes a step 1060 to fill the second openings with a second conductive material, thereby forming a plurality of second bonding elements in the second openings. In some embodiments, the filling the first openings and the filling the second openings are performed such that the first conductive material and the second conductive material have a same material composition

The method 1000 includes a step 1070 to electrically couple the first part of the CFET device and the second part of the CFET device together at least in part through the first bonding elements and the second bonding elements. In some embodiments, the electrically coupling comprises bonding the first bonding elements directly to the second bonding elements.

It is understood that the method 1000 may include additional steps that may be performed before, during, or after the steps 1010-1070. For example, in some embodiments, before the electrically coupling of step 1070 is performed, the method 1000 may include the following steps: forming a third dielectric layer over the first bonding elements; etching a plurality of third openings in the third dielectric layer; filling the third openings with a third conductive material, thereby forming a plurality of third bonding elements in the third openings, wherein at least a subset of the third bonding elements are formed directly on at least a subset of the first bonding elements; forming a fourth dielectric layer over the second bonding elements; etching a plurality of fourth openings in the fourth dielectric layer; and filling the fourth openings with a fourth conductive material, thereby forming a plurality of fourth bonding elements in the fourth openings, wherein at least a subset of the fourth bonding elements are formed directly on at least a subset of the second bonding elements. The electrically coupling of step 1070 comprises bonding the third bonding elements directly to the fourth bonding elements. As another example, the method 1000 may further include the following steps performed before the forming the first dielectric layer and the forming the second dielectric layer: forming one or more n-type transistors in the first part of the CFET; and forming one or more p-type transistors in the second part of the CFET. Other steps may include testing and packaging, etc.

In summary, the present disclosure involves a bonding alignment scheme. According to the scheme, one or more bonding structures may be formed over a top tier device of a parallel CFET, and one or more bonding structures may be formed over a bottom tier device of the parallel CFET. Each of the bonding structures may include a dielectric layer and a plurality of conductive components (serving as bonding elements) embedded in the dielectric layer. The conductive components may have wider lateral dimensions than the conductive vias to which they are coupled. In some embodiments, the conductive components of the bonding structure have a periodic distribution. The bonding of the top tier device and the bottom tier device of the parallel CFET is performed at least in part by bonding the bonding layers together, such that the conductive components of the bonding structure of the top tier device are bonded to the conductive components of the bonding structure of the bottom tier device.

The embodiments of the present disclosure offer advantages over conventional systems and methods of bonding. It is understood, however, that other embodiments may offer additional advantages, and not all advantages are necessarily disclosed herein, and that no particular advantage is required for all embodiments. One advantage is the greater margin for bonding alignment. In that regard, as device sizes get scaled down in each technology node of semiconductor fabrication, it may be increasingly more difficult to align the conductive vias from different IC structures, such as between the conductive vias from a top tier device of a CFET and the conductive vias from a bottom tier device if the CFET. However, since the present disclosure establishes the bonding (and therefore the electrical connectivity) between the top tier device and the bottom tier device of the CFET through the bonding elements-which are wider than the conductive vias—there is more tolerance for a lateral shift between the top tier device and the bottom tier device, and the bonding elements can still make electrical contact with one another, thereby enabling electrical connectivity between the top tier and bottom tier devices of the CFET. Another advantage is an improvement in the bonding itself. In that regard, the quality of the bonding may be dependent on the planarity of the bonding surfaces. By implementing the bonding elements as a periodic structure (e.g., having substantially equal sizes as one another and/or being spaced apart from one another at substantially uniform distances), the pattern uniformity is improved. The improved pattern uniformity may reduce a dishing effect and/or other planarization issues that may otherwise occur, and as a result, the planarity of the planarized surface may be improved. In embodiments where dummy bonding elements are implemented, the pattern uniformity may be further enhanced, which may further improve the planarity of the planarized surface. Consequently, the bonding surfaces (having better planarity) may enable a higher quality bonding, which is associated with better device performance and/or yield. Other advantages include compatibility with existing fabrication processes and the ease and low cost of implementation.

One aspect of the present disclosure pertains to a device. The device includes: a first device that includes a plurality of first transistors; a first bonding layer disposed over the first device, wherein the first bonding layer includes a first dielectric layer and a plurality of first conductive components embedded in the first dielectric layer; a second device that includes a plurality of second transistors; and a second bonding layer disposed over the second device, wherein the second bonding layer includes a second dielectric layer and a plurality of second conductive components embedded in the second dielectric layer, and wherein each of the first conductive components is aligned with, and coupled to, a respective one of the second conductive components.

Another aspect of the present disclosure pertains to a device. The device includes: a top portion of a complementary field effect transistor (CFET) device that includes a plurality of transistors having a first type of conductivity; a bottom portion of the CFET device that includes a plurality of transistors having a second type of conductivity different from the first type of conductivity; and a bonding structure disposed between the top portion of the CFET and the bottom portion of the CFET in a cross-sectional side view, wherein the bonding structure includes at least a first bonding layer that contains a plurality of first bonding elements and a second bonding layer that contains a plurality of second bonding elements, wherein the first bonding elements are vertically aligned with, and directly bonded to, the second bonding elements in the cross-sectional side view, and wherein the first bonding elements and the second bonding elements each have a periodic distribution in a top view.

Yet another aspect of the present disclosure pertains to a method. The method includes: forming a first dielectric layer over a first part of a complementary field effect transistor (CFET) device; etching a plurality of first openings in the first dielectric layer; filling the first openings with a first conductive material, thereby forming a plurality of first bonding elements in the first openings; forming a second dielectric layer over a second part of the CFET device; etching a plurality of second openings in the second dielectric layer; filling the second openings with a second conductive material, thereby forming a plurality of second bonding elements in the second openings; and electrically coupling the first part of the CFET device and the second part of the CFET device together at least in part through the first bonding elements and the second bonding elements.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first device that includes:
a plurality of first transistors; and
a first bonding layer disposed over the first device, wherein the first bonding layer includes a first dielectric layer and a plurality of first conductive components embedded in the first dielectric layer, wherein the first bonding layer is a part of a middle-end-of-line (MEoL) interconnection structure of the first device;
a second device that includes:
a plurality of second transistors; and
a second bonding layer disposed over the second device, wherein the second bonding layer includes a second dielectric layer and a plurality of second conductive components embedded in the second dielectric layer, wherein the second bonding layer is a part of a MEoL interconnection structure of the second device, and wherein each of the first conductive components is aligned with, and coupled to, a respective one of the second conductive components.

2. The device of claim 1, wherein:
the first device is a top device of a complementary field effect transistor (CFET), and the second device is a bottom device of the CFET; or
the first device is the bottom device of the CFET, and the second device is the top device of the CFET.

3. The device of claim 1, wherein:
the first transistors include n-type transistors; and
the second transistors include p-type transistors.

4. The device of claim 1, further comprising:
a third bonding layer disposed over the first bonding layer, wherein the third bonding layer includes a third dielectric layer and a plurality of third conductive components embedded in the third dielectric layer; and
a fourth bonding layer disposed over the second bonding layer, wherein the fourth bonding layer includes a fourth dielectric layer and a plurality of fourth conductive components embedded in the fourth dielectric layer;
wherein:
the third conductive components are directly bonded to the fourth conductive components;
at least a subset of the third conductive components is electrically coupled to the first conductive components; and
at least a subset of the fourth conductive components is electrically coupled to the second conductive components.

5. The device of claim 4, wherein:
at least a further subset of the third conductive components are dummy conductive components that are not electrically coupled to any of the first conductive components; or
at least a further subset of the fourth conductive components are dummy conductive components that are not electrically coupled to any of the second conductive components.

6. The device of claim 1, wherein the first device and the second device each further includes a back-end-of-line (BEoL) interconnection structure, respectively, wherein the MEoL interconnection structure and the BEoL interconnection structure of the first device are located on opposite sides of the first transistors, and wherein the MEoL interconnection structure and the BEoL interconnection structure of the second device are located on opposite sides of the second transistors.

7. The device of claim 1, wherein the first conductive components and the second conductive components have identical profiles in a top view.

8. The device of claim 1, wherein the first conductive components and the second conductive components each have a periodic distribution pattern in a top view.

9. The device of claim 1, wherein:
a first side of one of the first conductive components is bonded to a first conductive via or a first conductive contact of the first device;
a first side of one of the second conductive components is bonded to a second conductive via or a second conductive contact of the second device;
a second side of the one of the first conductive components is bonded to a second side of one of the second conductive components; and
the first conductive via or the first conductive contact is laterally offset from the second conductive via or the second conductive contact in a cross-sectional side view.

10. The device of claim 1, wherein:
the first dielectric layer and the second dielectric layer have a same dielectric material composition; and
the first conductive components and the second conductive components have a same conductive material composition.

11. A device, comprising:
a top portion of a complementary field effect transistor (CFET) device that includes a plurality of transistors having a first type of conductivity;
a bottom portion of the CFET device that includes a plurality of transistors having a second type of conductivity different from the first type of conductivity; and
a bonding structure disposed between the top portion of the CFET and the bottom portion of the CFET in a cross-sectional side view, wherein the bonding structure includes at least a first bonding layer that contains a plurality of first bonding elements and a second bonding layer that contains a plurality of second bonding elements, wherein the first bonding elements are vertically aligned with, and directly bonded to, the second bonding elements in the cross-sectional side view, and wherein the first bonding elements and the second bonding elements each have a periodic distribution in a top view.

12. The device of claim 11, wherein:
the bonding structure further includes a third bonding layer and a fourth bonding layer;
the third bonding layer is disposed between the top portion of the CFET and the first bonding layer in the cross-sectional side view;
the third bonding layer includes a plurality of third bonding elements that are electrically coupled to at least a subset of the first bonding elements;
the fourth bonding layer is disposed between the bottom portion of the CFET and the second bonding layer in the cross-sectional side view;
the fourth bonding layer includes a plurality of fourth bonding elements that are electrically coupled to at least a subset of the second bonding elements; and
at least one of the third bonding elements is electrically coupled to, but misaligned with, one of the fourth bonding elements.

13. The device of claim 11, wherein:
a subset of the first bonding elements are not electrically coupled to any microelectronic component of the top portion of the CFET; or
a subset of the second bonding elements are not electrically coupled to any microelectronic component of the bottom portion of the CFET.

14. A method, comprising:
forming a first dielectric layer over a first part of a complementary field effect transistor (CFET) device;
etching a plurality of first openings in the first dielectric layer;
filling the first openings with a first conductive material, thereby forming a plurality of first bonding elements in the first openings;
forming a second dielectric layer over a second part of the CFET device;
etching a plurality of second openings in the second dielectric layer;
filling the second openings with a second conductive material, thereby forming a plurality of second bonding elements in the second openings; and
electrically coupling the first part of the CFET device and the second part of the CFET device together at least in part through the first bonding elements and the second bonding elements.

15. The method of claim 14, wherein the electrically coupling comprises bonding the first bonding elements directly to the second bonding elements.

16. The method of claim 14, further comprising, before the electrically coupling:
forming a third dielectric layer over the first bonding elements;
etching a plurality of third openings in the third dielectric layer;
filling the third openings with a third conductive material, thereby forming a plurality of third bonding elements in the third openings, wherein at least a subset of the third bonding elements are formed directly on at least a subset of the first bonding elements;
forming a fourth dielectric layer over the second bonding elements;
etching a plurality of fourth openings in the fourth dielectric layer; and
filling the fourth openings with a fourth conductive material, thereby forming a plurality of fourth bonding elements in the fourth openings, wherein at least a subset of the fourth bonding elements are formed directly on at least a subset of the second bonding elements;
wherein the electrically coupling comprises bonding the third bonding elements directly to the fourth bonding elements.

17. The method of claim 14, wherein the filling the first openings and the filling the second openings are performed such that the first conductive material and the second conductive material have a same material composition.

18. The method of claim 14, further comprising, before the forming the first dielectric layer and the forming the second dielectric layer:
forming one or more n-type transistors in the first part of the CFET; and
forming one or more p-type transistors in the second part of the CFET.

19. The method of claim 14, wherein the first openings and the second openings are etched in a manner such that each of the first openings is vertically aligned with a respective one of the second openings in a cross-sectional side view.

20. The method of claim 14, wherein the first openings and the second openings are etched in a manner such that the first openings and the second openings each have a periodic distribution in a top view.
